(19) United States
(12) Patent Application Publication
(10) Pub. No.: US 2013/0074905 A1
(43) Pub. Date: Mar. 28, 2013

(54) PHOTOVOLTAIC DEVICE WITH REFLECTIVE STACK

(71) Applicant: Benyamin Buller, Perrysburg, OH (US)

(72) Inventor: Benyamin Buller, Perrysburg, OH (US)

(21) Appl. No.: 13/615,834

(22) Filed: Sep. 14, 2012

Related U.S. Application Data
(60) Provisional application No. 61/539,293, filed on Sep. 26, 2011.

(51) Int. Cl. H01L 31/0232; H01L 31/18; H01L 31/024

(52) U.S. Cl. 136/246; 438/72; 257/E31.127

(57) ABSTRACT

A photovoltaic device that includes a reflective stack. The reflective stack is formed from a transparent material between two metal layers. The reflective stack is located within the photovoltaic device to partially reflect wavelengths of radiation that do not substantially contribute to the photovoltaic effect.

### CROSS-REFERENCE TO RELATED APPLICATION

This application claims priority to U.S. Provisional Application No. 61/539,293, filed on Sep. 26, 2011, the disclosure of which is incorporated by reference in its entirety.

### FIELD OF THE INVENTION

Disclosed embodiments relate to the field of photovoltaic power generation systems, and more particularly to a photovoltaic device and manufacturing method thereof.

### BACKGROUND

A photovoltaic device, such as a photovoltaic module or cell, converts sun radiation directly into electrical current by the photovoltaic effect. For most photovoltaic devices, only a portion of the spectrum of sun radiation is utilized to generate electrical current. The remaining portions of the spectrum of sun radiation are typically absorbed by, and heat, the photovoltaic devices. A rise in temperature of a photovoltaic device generally decreases the efficiency with which the device generates electrical current. Accordingly, a photovoltaic device with improved efficiency is desirable.

### BRIEF DESCRIPTION OF THE DRAWINGS

FIG. 1 is a cross-sectional view of a structure in accordance with a disclosed embodiment.

FIG. 2 is the cross-sectional view of the structure of FIG. 1 illustrating radiation being reflected in accordance with a disclosed embodiment.

FIG. 3 is a cross-sectional view of another structure in accordance with a disclosed embodiment.

FIG. 4 is a cross-sectional view of another structure in accordance with a disclosed embodiment.

FIG. 5 is a diagram illustrating the formation of a structure in accordance with a disclosed embodiment.

### DETAILED DESCRIPTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or procedural changes may be made to the specific embodiments disclosed without departing from the spirit and scope of the invention.

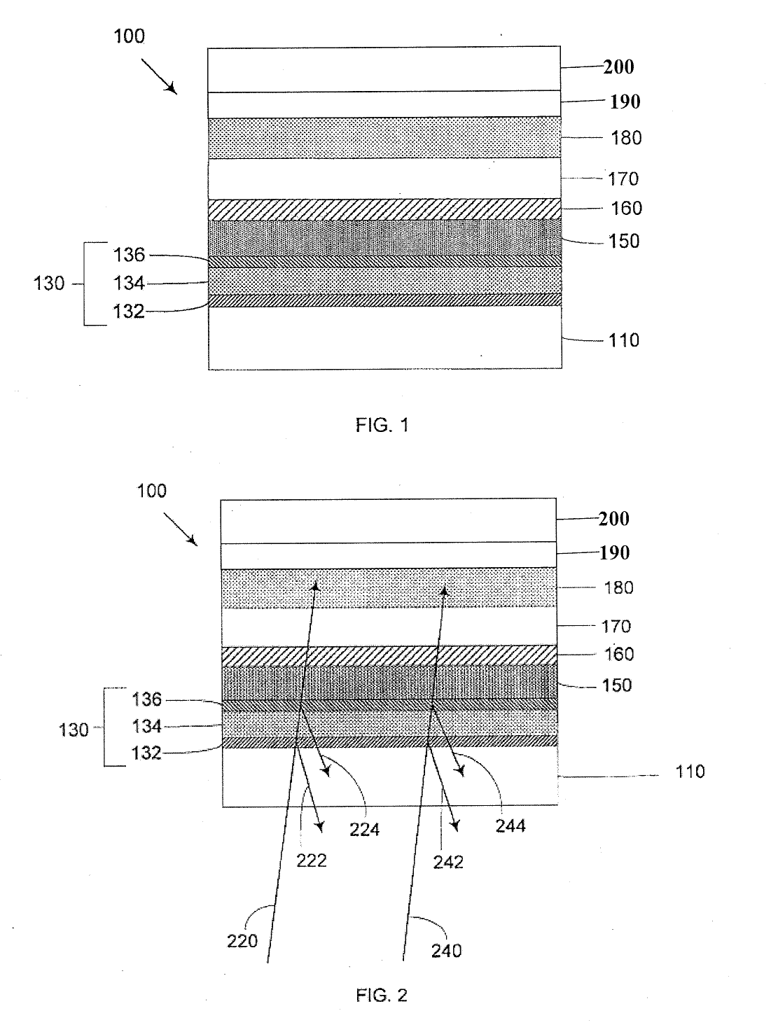

FIG. 1 is a cross-sectional view of a substrate structure 100 used for photovoltaic devices, such as photovoltaic modules or cells, in accordance with a disclosed embodiment. The structure 100 comprises multiple sequential layers of various materials deposited on a front support 110. In one exemplary embodiment, layers of the structure 100 may include reflective stack layers 130, one or more transparent conductive oxide (TCO) layers 150, optionally, one or more buffer layers 160, at least one semiconductor window layer 170, at least one semiconductor absorber layer 180, a back contact layer 190, and a back support layer 200. The front support layer 110 is made of an insulative material that is transparent or translucent to radiation, such as soda lime glass, low iron glass, solar float glass or other suitable glass. The back support layer 200 may be formed of similar materials as the front support layer 110. The TCO layer(s) 150 may be doped tin oxide, cadmium tin oxide, tin oxide, indium oxide, zinc oxide, other transparent conductive oxides, or a combination thereof.

The buffer layer(s) 160 may be tin oxide, zinc tin oxide, zinc magnesium oxide, zinc sulfur oxide, other transparent conductive oxides, or a combination thereof. The absorber layer 180 may generate photo carriers upon absorption of solar radiation and may be made of amorphous silicon, copper indium gallium diselenide, cadmium telluride or any other suitable radiation absorbing material. In one embodiment, the window layer 170 may mitigate the internal loss of photo carriers (e.g., electrons and holes) in the structure 100. The window layer 170 is a semiconductor material, such as cadium sulfide, zinc sulfide, cadium zinc sulfide, zinc magnesium oxide or any other suitable photovoltaic semiconductor material. The back contact layer 190 may be one or more metal layers and may be formed of molybdenum, aluminum, chromium, iron, nickel, titanium, vanadium, manganese, cobalt, zinc, ruthenium, tungsten, silver, gold, copper, mercury tellurium, titanium disilicide, titanium silicide, molybdenum nitride, titanium nitride, tungsten nitride, platinum, or similar materials.

It should be noted that structure 100 is not intended to be considered a limitation on the types of photovoltaic devices to which the present disclosure may be applied, but rather a convenient representation for the following description. In addition, each of the layers 110, 130, 150, 160, 170, 180, 190, 200 may include one or more layers or films, one or more different types of materials and/or same material types with differing compositions. And although the layers 130, 150, 160, 170, 180, 190, 200 are shown as being formed on the front support layer 110, structure 100 can also be built up from back support layer 200 using various material layers known in the art. The layers can also have differing thicknesses and other dimensions. Other materials may be optionally included in the structure 100 beyond what is mentioned to further improve performance.

The reflective stack 130 reflects undesired wavelengths of solar radiation away from the structure 100. Solar radiation has significant power in the spectral range of 300-2500 nm that may be used to generate current. Most photovoltaic devices, however, are unable to use this entire spectral range to generate significant amounts of current and instead only rely on specific wavelength bands to generate current. For example, photovoltaic devices that use cadmium telluride in the absorber layer 180 may rely on wavelengths of radiation between 300 nm and 850 nm as useful wavelengths of radiation to generate current. The remaining portions of the solar radiation with significant power (i.e. radiation with wavelengths between 850 nm and 2500 nm) are absorbed by the layers in the photovoltaic device and heat the device. The portions of solar radiation that generate little or no current and heat the device, thereby lowering the operating efficiency of the device, are considered to be non-useful wavelengths of radiation. The TCO layer 150, the buffer layer 160, the window layer 170, the absorber layer 180, and the back-contact layer 190 may all absorb these non-useful wavelengths of radiation. Other layers within a photovoltaic device may also absorb these non-useful wavelengths of radiation. As another example, photovoltaic devices that use cadium sulfide and copper indium gallium diselenide in the absorber layer 180 may only use wavelengths of radiation between 300 nm and 1100 nm to generate current. The remaining non-useful portions of the solar radiation with significant power (i.e. radiation with wavelengths between 1100 nm and 2500 nm) may be absorbed by the layers in the photovoltaic device and heat the device.

These non-useful wavelengths, when absorbed undesirably, heat the photovoltaic device making it less efficient. For example, in some photovoltaic devices, each time the temperature of the device raises a single degree Celsius, the device generates 0.25% less power.

Referring again to FIG. 1, the reflective stack 130 reflects undesired wavelengths of solar radiation away from the structure 100. In this exemplary embodiment, the reflective stack 130 comprises a first metal layer 132, a second metal layer 136, and a transparent material layer 134 that is located between the first and second metal layers 132 and 136. Each of layers 132, 134, and 136 may pass wavelengths of radiation useful for generating electrical energy with a photovoltaic device. The first and second metal layers 132 and 136 are metal materials such as molybdenum, tantalum, zirconium, tungsten, vanadium, titanium, chromium, copper, cobalt, aluminum, silver, niobium, their alloys, or any other suitable metallic material. In one embodiment, the first and second metal layers 132 and 136 may be of the same material. In another embodiment, the first and second metal layers 132 and 136 may be of different materials. Furthermore, the processing technique used to form subsequent layers in the structure 100 may limit the choice of metal materials. For example, high temperature processing of the structure 100 may preclude the use of silver or aluminum. The transparent material layer 134 may be a dielectric such as silicon dioxide, titanium dioxide, zirconium oxide, aluminum oxide, a combination of these materials, or any other suitable dielectric. The transparent material layer 134 may also be a semi-conductive material, such as doped tin dioxide, zinc oxide, silicon dioxide, or any other suitable semi-conductive material.

The reflective stack 130 reduces the intensity of non-useful radiation that is typically absorbed by the structure 100 by reflecting portions of the non-useful radiation. Reducing the intensity of the non-useful radiation reduces the heat generated by the absorption of this non-useful radiation. By reducing the amount of heat generated by absorption of radiation, the structure 100 may operate at a lower temperature and, thus, more efficiently. The intensity of radiation transmitted through the TCO layer 150, buffer layer 160, window layer 170, and the absorber layer 180 and the amount absorbed by these layers equals the total intensity of the radiation minus the combined intensity of the reflections caused by the reflective stack 130.

The reflective stack 130 further increases the efficiency of the device by reducing reflections of the useful wavelengths of radiation. In this way, all of the intensity of the useful wavelengths of radiation may be used by the structure 100 to generate current. In particular, the reflective stack 130 operates to eliminate reflections for a wavelength of radiation in the center of the useful range of radiation. For example, in one embodiment, the structure 100 may have a semiconductor layer that includes cadmium telluride where the center of the useful range of radiation is 650 nm. In this embodiment, the reflective stack 130 produces no reflection of radiation having a wavelength of 650 nm. The reflective stack 130 also reduces undesired reflections for the remaining useful wavelengths of radiation. However, the amount of reflection reduction for a particular wavelength is reduced the farther that the particular wavelength is from the center wavelength. For example, if the center wavelength is 650 nm, then the reflection reduction for wavelengths of 725 nm is less than the reflection reduction for wavelengths of 675 nm. As a result, wavelengths farther from the center wavelength have reduced intensities as compared to wavelengths closer to the center wavelength. Details with respect to how the reflective stack 130 reflects the non-useful wavelengths of radiation and reduces reflections of the useful wavelengths of radiation are described below with regard to FIG. 2.

FIG. 2 illustrates useful radiation 220 and non-useful radiation 240 entering the structure 100, passing through the reflective stack 130, and transmitting into the TCO layer 150, the buffer layer 160, the window layer 170, and the absorber layer 180 according to an exemplary embodiment. FIG. 2 further illustrates that a portion of the useful radiation 220 is reflected when the useful radiation 220 transitions through first metal layer 132, creating first useful radiation reflection 222. As a result of the first useful radiation reflection 222, the intensity of the useful radiation 220 that is transmitted into the transparent material layer 134 is decreased as compared to the intensity of the useful radiation 220 transmitted to the first metal layer 132. The intensity or absolute amplitude of the first useful radiation reflection 222 is determined by the thickness of the first metal layer 132. In this embodiment, the thickness of the first metal layer 132 is between 10 to 100 angstroms thick. It should be noted that as the thickness of the first metal layer 132 increases, the intensity of the first useful radiation reflection 222 increases.

A second portion of the useful radiation 220 is reflected when the useful radiation 220 transitions through the second metal layer 136, creating second useful radiation reflection 224. The intensity of the second useful radiation reflection 224 is determined by the thickness of the second metal layer 136. In this embodiment, the thickness of the second metal layer 136 is between 10 to 100 angstroms thick. Similar to the first metal layer 132, as the thickness of the second metal layer 136 increases the intensity of the second useful radiation reflection 224 increases.

In order to reduce the undesired reflection of the useful radiation 220, the reflective stack 130 causes the first and second useful radiation reflections 222 and 224 to destructively interfere. When the first and second useful radiations reflections 222 and 224 completely destructively interfere, the combined intensities of the reflections 222 and 224 equals zero. As noted earlier, the intensity of transmitted radiation equals the intensity of the radiation minus the combined intensity of any reflections and minus the intensity of light that was absorbed in the reflective stack layers 130. Because the combined intensities of the first and second useful reflections 222 and 224 equal zero, the intensity of the useful radiation 220 is maximized as it is transmitted through the reflective stack 130.

To cause complete destructive interference between the first and second useful radiations reflections 222 and 224, the intensities of the first and second useful radiation reflections 222 and 224 need to be the same. As noted above, the intensities of the first and second useful radiation reflections 222 and 224 are controlled by the thickness of the first and second metal layers 132 and 136 respectively. To match the intensities, the second metal layer 136 needs to be thicker than the thickness of the first metal layer 132 because a greater percentage of the intensity of the useful radiation 220 is required to create a second useful radiation reflection 224 with an intensity equal to the intensity of the first useful radiation reflection 222. This is necessary because the intensity of the useful radiation 220 is less when the second useful radiation reflection 224 is created than when the first useful radiation reflection 222 is created. It should be noted that the embodiment is not limited to just one set of thicknesses for the first and second metal layers 132 and 136 that may be used to match the intensities of the first and second useful radiation reflections 222 and 224. Rather, more than one set of thicknesses for the first and second metal layers 132 and 136 may be used to match the intensities of the first and second useful radiation reflections 222 and 224.

In addition to matching the intensities of the first and second useful radiation reflections 222 and 224, to cause complete destructive interference between the first and second useful radiations reflections 222 and 224 the phases of the first and second useful radiation reflections 222 and 224 need to be offset by 180 degrees. An offset of 180 degrees occurs when λ(M−½)=2*N*D, where λ equals the wavelength of the radiation, N equals the refractive index of the transparent material 134, D equals the thickness of the transparent material, and M is an integer. Accordingly, the phases of the first and second useful radiation reflections 222 and 224 may be offset by adjusting the thickness (D) of the transparent material 134. For example, in the embodiment depicted in FIG. 2, if the transparent material 134 has an index of refraction (N) of 2.5 and the integer M=1, the thickness (D) of the transparent material layer 134 is ¼ of 650 nm divided by 2.5, or approximately 65 nm. It should be appreciated that other thicknesses of the transparent material layer 134 may also be used to achieve a 180-degree phase shift.

In this embodiment, the thickness of the layers 132, 134, and 136 are selected to cause complete destructive interference of wavelengths of 650 nm. Wavelengths of useful radiation 220 other than 650 nm will also experience destructive interference of reflections; however, they do not experience complete destructive interference because the reflections of these wavelengths are not exactly 180 degrees out-of-phase. As a result, some of the intensity of these wavelengths is reflected and not transmitted to the remaining layers of the structure 100. However, because some destructive interference occurs between the reflections at other wavelengths, the transmitted intensity is greater than if no destructive interference had occurred. Furthermore, due to the existence of other reflective interfaces in the structure 100, the thickness of the layers in the reflective stack 130 may be further optimized to minimize reflections for other wavelengths of radiation within the useful range of radiation. It should be understood that in practice, complete destructive interference may not occur even at the wavelength for which the device is optimally designed because the thicknesses of the layers in the reflective stack 130 may not have the exact thickness required to produce complete destructive interference. However, the concepts and theories explained herein may be used to reduce reflections of useful radiation in a reflective stack.

Referring again to FIG. 2, reflection of the unused wavelengths of radiation is now described. Similarly to the useful radiation 220, a portion of the non-useful radiation 240 is reflected when the non-useful radiation 240 transitions through the first metal layer 132, creating first non-useful radiation reflection 242. As a result of the first non-useful radiation reflection 242, the intensity of the non-useful radiation 240 decreases. A second portion of the non-useful radiation 240 is reflected when the non-useful radiation 240 transitions through the second metal layer 136, creating a second non-useful radiation reflection 244. Thus, the intensity of the non-useful radiation 240 further decreases. In the instance of the non-useful radiation 240, the transparent material layer 134 causes the first and second non-useful radiation reflections 242 and 244 to have similar phases leading to the first and second non-useful radiation reflections 242 and 244 constructively interfering. This constructive interference produces greater reflections of the non-useful radiation 240 thereby lowering the intensity of the non-useful radiation 240 that may be absorbed by the structure 100.

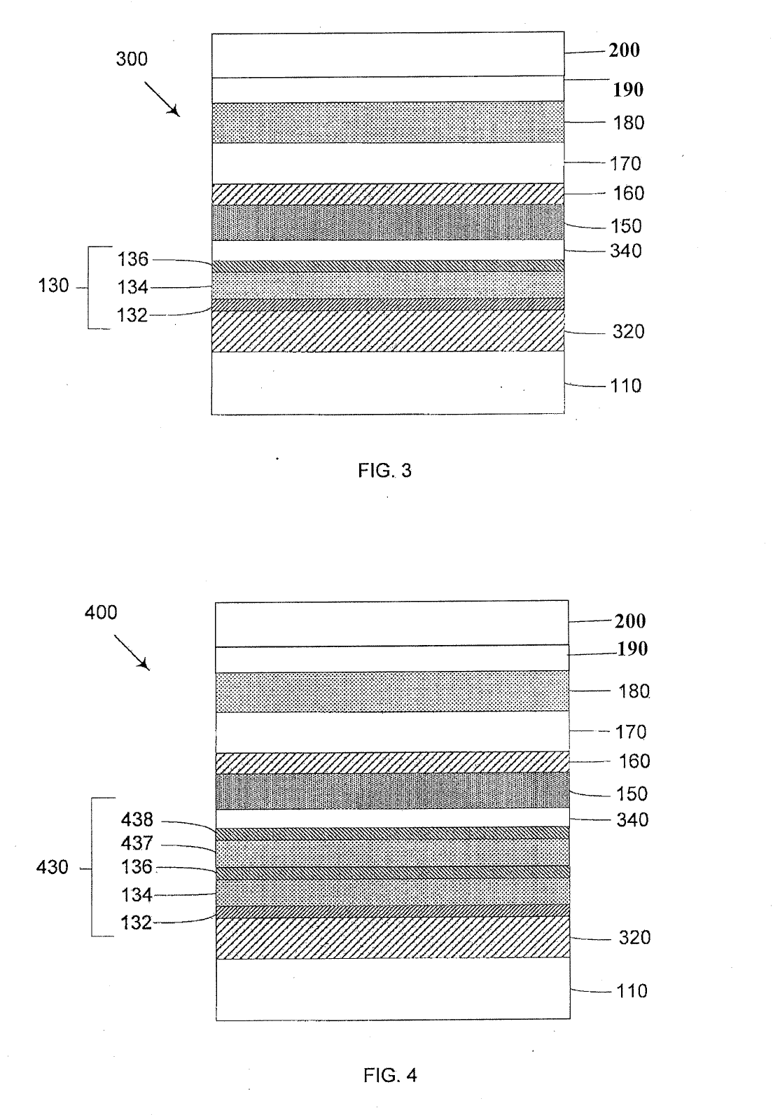

FIG. 3 illustrates a structure 300 according to another exemplary embodiment. Structure 300 includes the layers described above with respect to FIG. 1 and further includes a barrier layer 320 and a second buffer layer 340. The barrier layer 320 is located between the front support 110 and reflective stack 130. The barrier layer 320 may be silicon oxide, silicon aluminum oxide, tin oxide, other suitable material, or a combination thereof. The barrier layer 320 reduces the likelihood of ions and impurities from the front support 110 diffusing into the first metal layer 132 during processing of the structure 300, which could lead to separation between layers, sensitivity to moisture, and reduction in the optical properties of the structure 300.

The second buffer layer 340 is located between the TCO layer 150 and the reflective stack 130. In various embodiments, the second buffer layer 340 may be formed from tin oxide, zinc tin oxide, zinc magnesium oxide, zinc sulfur oxide, other TCO, other similar materials, or a combination thereof. In other embodiments, the second buffer layer 340 may be formed from a suitable dielectric material such as silicon oxide or silicon aluminum oxide. The second buffer layer 340 reduces the number of ions that may diffuse into the reflective stack 130 from other layers during processing of the structure 300, which could lead to separation between layers, sensitivity to moisture, and reduction in the optical properties of the structure 300. The second buffer layer 340 reduces the number of ions that may diffuse from the substrate 110 or the reflective stack 130 into the semiconductor layers during processing of the structure 300 and improve adhesion between layers 130 and 150.

Furthermore, in the FIG. 3 embodiment, the transparent material layer 134 may be tin oxide, zinc tin oxide, zinc magnesium oxide, zinc sulfur oxide, other TCO, other semi-conductive materials, or a combination thereof as long as the transparent material layer 134 is partially conductive. If the transparent material layer 134 and second buffer layer 340 are partially conductive, the first and second metal layers 132 and 136 act as conductors in parallel with the TCO layer 150 to carry current generated by the structure 300 laterally to the edge of the structure 300. For example, in one embodiment, the first and second metal layers 132 and 136 and the TCO layer 150 may each have a sheet resistance of 20 ohms per square. If the transparent material 134 and the second buffer layer 340 have resistivity less than one mega ohm per cm then the first and second metal layers 132 and 136 are electrically connected in parallel with the TCO layer 150. With the TCO layer 150 and the first and second metal layers 132 and 136 connected in parallel, their combined parallel resistance is equal to the total sheet resistance for the conducting lateral current. Because the first and second metal layers 132 and 136 and the TCO layer 150 each have a sheet resistance of 20 ohms per square, the total sheet resistance for conducting lateral current would be approximately 6.66 ohms per square. An ideal sheet resistance for a TCO layer is 6 ohms per square.

With the first and second metal layers 132 and 136 electrically connected in parallel with the TCO layer 150, the resistivity of the TCO layer 150 may be higher than if the TCO layer 150 was solely responsible for conducting current laterally to the edge of the structure 300. As a result, the thickness of the TCO layer 150 may be reduced. The reduction in the thickness of the TCO layer 150 may be more than the thickness of the additional layers, resulting in the overall reduction of the thickness of the structure 300. Furthermore, the cost of the material for the TCO layer 150 may be higher than the costs for the additional layers. As a result, the overall costs of materials for the structure 300 may also be reduced even though additional costs are incurred for the additional layers. Additionally, the reduction in the thickness of the TCO layer 150 may further reduce absorption of the non-useful radiation 240 and thereby increase the overall efficiency of the structure 300 because the TCO layer 150 absorbs much of the non-useful radiation 240. Additionally, the reduction in the thickness of the TCO layer 150 may further reduce absorption of the useful radiation 220 in the TCO layer 150 and thereby increasing the overall efficiency of the structure 300 because more light will be transmitted into the absorber layer 180.

FIG. 4 illustrates another structure 400 according to an exemplary embodiment. The structure 400 includes the layers described with respect to FIG. 3 and further includes reflective stack 430 including a third metal layer 438 and a second transparent material layer 437. The second transparent material layer 437 is located above the second metal layer 136 and the third metal layer 438 is located between the second buffer layer 340 and the second metal layer 136.

The third metal layer 438 is a metal material such as molybdenum, tantalum, zirconium, tungsten, vanadium, titanium, chromium, copper, cobalt, aluminum, silver, niobium, their alloys, or any other suitable metallic material. Furthermore, the third metal layer 438 may be of the same material as the first and second metal layers 132 and 136 or it may be different. The second transparent material layer 437 may be a dielectric such as silicon dioxide, titanium dioxide, zirconium oxide, aluminum oxide, a combination of these materials, or any other suitable dielectric. Alternatively, second transparent material layer 437 may also be a semi-conductive material, such as doped tin dioxide, zinc oxide, silicon dioxide, or any other suitable semi-conductive material. Furthermore, the second transparent material layer 437 may be the same material as the transparent material layer 134 or it may be different.

The third metal layer 438 and the second transparent material layer 437 are used to further increase the transmission of useful radiation 220 and the reflection of non-useful radiation 240. Furthermore, the thicknesses of the third metal layer 438 and the second transparent material layer 437 may be adjusted according to the thickness of the first and second metal layers 132 and 136, the transparent material layer 134, and other reflective surfaces in the structure 400 to increase the intensity of transmission of a wider band of useful radiation 220 and reflections of a wider band of non-useful radiation 240. It should be noted that the particular configurations of the reflective stack of the embodiments may be determined by one of ordinary skill in the art manually or using, for example, available software programs for calculating the reflection, absorption, and transmission of light at wavelengths within a range of interest based on the properties of the particular materials being used, such as the wavelength dependent refractive index of the material and the material's absorption coefficient. It should also be noted that additional metal and transparent material layers may be used to optimize the performance of a reflective stack. Furthermore, it should be understood that an optimal design may be dependent on the application and other manufacturing considerations and constraints.

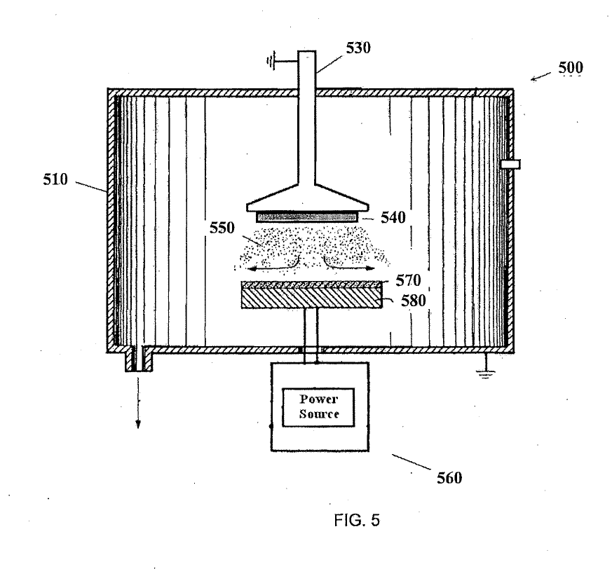

FIG. 5 illustrates a sputter system 500 that is one apparatus that may be used to form the various layers of a reflective stack 130 or 430 according to an exemplary embodiment. The sputter system 500 is a DC sputtering system that includes a chamber 510 and a pulsed DC power supply 560 with a pulse of any suitable length, such as 4 microseconds. The power output of the source may range from about 3 kW (˜1.4 W/cm²) to about 9 kW (˜4.2 W/cm²). The target voltage may range from about 300 volts to about 420 volts.

Within the chamber 510, a structure 570 (e.g. the front support 110) upon which the reflective stack 130 is formed is mounted on a plate or holder 580 or positioned in any other suitable manner. A metal/alloy/compound target 540 is held within a distance of 50 mm to 500 mm of the structure 570 by a grounded fixture 530. The target 540 may be a ceramic target or a metallic target and may be prepared by casting, sintering, or various thermal spray methods. The chamber 510 is filled with an ambient gas such as helium, neon, argon, krypton, xenon, or other suitable gasses at a pressure ranging from about 2.0 mTorr to about 8.0 mTorr. During the sputtering process, particles 550 from the target 540 are deposited onto the structure 570 to form a reflective stack. The sputtering process may also be used to form other layers in a photovoltaic device.

In another embodiment, the sputter system 500 may be a RF sputtering system or a matching circuit AC sputtering system. Furthermore, the various layers of reflective stack 130 or 430 may be formed through physical deposition, chemical deposition, or any other deposition method.

While embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

What is claimed as new and desired to be protected by Letters Patent of the United States is:

1. A photovoltaic device comprising:
a reflective stack comprising:
a first metal material,
a second metal material,
a transparent dielectric material between the first and second metal materials;
first and second semiconductor materials; and
a transparent conductive oxide material between the reflective stack and the first and second semiconductor materials, wherein the reflective stack allows wavelengths of radiation which contribute to photovoltaic conversion to pass through to the semiconductor materials while reflecting wavelengths of radiation which do not substantially contribute to photovoltaic conversion.

2. The photovoltaic device of claim 1, wherein a thickness of the transparent dielectric material in the reflective stack causes constructive interference of the reflections of the wavelengths of radiation which do not substantially contribute to photovoltaic conversion.

3. The photovoltaic device of claim 1, wherein a thickness of the transparent dielectric material in the reflective stack causes destructive interference of reflections of wavelengths of radiation which contribute to photovoltaic conversion.

4. The photovoltaic device of claim 1, wherein the wavelengths of radiation which do not substantially contribute to photovoltaic conversion are longer than 850 nanometers.

5. The photovoltaic device of claim 1, wherein the wavelengths of radiation which do not substantially contribute to photovoltaic conversion are longer than 1100 nanometers.

6. The photovoltaic device of claim 1, wherein the first metal material has a thickness between 10 and 100 angstroms.

7. The photovoltaic device of claim 6, wherein the second metal material has a thickness greater than the thickness of the first metal material.

8. The photovoltaic device of claim 1, wherein the first and second metal materials are the same material.

9. The photovoltaic device of claim 1, wherein the first and second metal materials are selected from a group consisting of molybdenum, tantalum, zirconium, tungsten, vanadium, titanium, chromium, copper, cobalt, aluminum, silver, niobium, and their alloys.

10. The photovoltaic device of claim 1, further comprising a buffer material between the reflective stack and the transparent conductive oxide material.

11. The photovoltaic device of claim 1, further comprising a substrate and a barrier material adjacent to the substrate, the reflective stack being adjacent to the barrier material.

12. The photovoltaic device of claim 1, wherein the reflective stack further comprises:
a third metal material between the transparent conductive oxide material and the second metal material; and
a second transparent material between the second and third metal materials.

13. The photovoltaic device of claim 12, wherein the second transparent material is conductive.

14. The photovoltaic device of claim 13, wherein the second and third metal materials and the transparent conductive oxide material have a combined sheet resistance of less than 7 ohms per square and conduct current generated by the photovoltaic device.

15. A photovoltaic device comprising:
a support material;
first and second semiconductor materials;
a conductive material between the support material and the first and second semiconductor materials,
a first metal material between the support material and the conductive material;
a second metal material between the support material and the conductive material; and
a transparent dielectric material between the first and second metal materials; wherein the first and second metal materials and the transparent material allow wavelengths of radiation, which contribute to photovoltaic conversion, to pass through to the semiconductor materials while reflecting wavelengths of radiation which do not substantially contribute to photovoltaic conversion.

16. A photovoltaic device comprising:
a barrier layer in contact with a support layer;
a reflective stack in contact with the barrier layer, the reflective stack comprising:
a first metal material,
a second metal material,
a transparent material between the first and second metal materials;
first and second semiconductor materials arranged with respect to the reflective stack so that radiation pass through the reflective stack before entering the first- and second semiconductor materials, wherein a thickness of the transparent material causes reflections of wavelengths of radiation from the first and second metal materials to destructively interfere.

17. A method of increasing the efficiency of a photovoltaic device comprising:
forming a reflective stack by: forming a first metal material, forming a second metal material, and forming a transparent dielectric material between the first and second metal materials;
forming first and second semiconductor materials; and
forming a transparent conductive oxide material between the reflective stack and the first and second semiconductor materials, wherein the reflective stack allows wavelengths of radiation which contribute to photovoltaic conversion to pass through to the semiconductor materials while reflecting wavelengths of radiation which do not substantially contribute to photovoltaic conversion.

18. The method of claim 17, wherein a thickness of the transparent dielectric material in the reflective stack causes constructive interference of the reflections of the wavelengths of radiation that are converted into heat by the photovoltaic device.

19. The method of claim 17, wherein a thickness of the transparent dielectric material in the reflective stack causes destructive interference of reflections of wavelengths of radiation that are converted into electrical current by the photovoltaic device.

20. The method of claim 17, wherein the wavelengths of radiation which do not substantially contribute to photovoltaic conversion are longer than 850 nanometers.

21. The method of claim 17, wherein the wavelengths of radiation which do not substantially contribute to photovoltaic conversion are longer than 1100 nanometers.

22. The method of claim 17, wherein the first metal material is formed with a thickness between 10 and 100 angstroms.

23. The method of claim 22, wherein the second metal material is formed with a thickness greater than a thickness of the first metal material.

24. The method of claim 17, wherein the first and second metal materials are formed from the same material.

25. The method of claim 17, wherein the first and second metal materials are selected from a group consisting of molybdenum, tantalum, zirconium, tungsten, vanadium, titanium, chromium, copper, cobalt, aluminum, silver, niobium, and their alloys.

26. The method of claim 17, further comprising forming a buffer material between the reflective stack and the transparent conductive oxide material.

27. The method of claim 17, further comprising forming a support structure material and a barrier material adjacent to the support structure material, the reflective stack being adjacent to the barrier material.

28. The method of claim 17, wherein step of forming the reflective stack further comprises forming a third metal material between the transparent conductive oxide material and the second metal material and forming a second transparent material between the second and third metal materials.

29. The method of claim 28, wherein the second transparent material is conductive.

30. The method of claim 29, wherein the second and third metal materials and the transparent conductive oxide material have a combined sheet resistance of less than 7 ohms per square and conduct current generated by the photovoltaic device.
